(19) United States
(12) Patent Application Publication
(10) Pub. No.: US 2025/0359139 A1
(43) Pub. Date: Nov. 20, 2025

(54) SUBSTRATE DEVICE

(71) Applicant: SAMSUNG ELECTRONICS CO., LTD., Suwon-si (KR)

(72) Inventors: Myoungsoo Kim, Suwon-si (KR); Minyoung Kim, Suwon-si (KR); Seongsik Min, Suwon-si (KR)

(73) Assignee: SAMSUNG ELECTRONICS CO., LTD., Suwon-si (KR)

(21) Appl. No.: 18/974,335

(22) Filed: Dec. 9, 2024

(30) Foreign Application Priority Data
May 17, 2024 (KR) 10-2024-0064344

(51) Int. Cl. H10D 30/65; G02F 1/133; H10D 30/01

(52) U.S. Cl. CPC H10D 30/65; H10D 30/0281; G02F 1/13306

(57) ABSTRACT

A semiconductor device may be provided and include: a semiconductor substrate including a semiconductor substrate; an active region on the semiconductor substrate; a device isolation region on a side surface of the active region; a first source/drain region and a second source/drain region spaced apart from each other within the active region; a channel region between the first source/drain region and the second source/drain region, within the active region; a gate electrode extending across the active region in a first direction and onto the device isolation region, and vertically overlapping with the channel region, the gate electrode having a first side surface and a second side surface opposite to each other in a second direction, perpendicular to the first direction; and a first blocking layer on a portion of the first source/drain region.

### CROSS-REFERENCE TO RELATED APPLICATION

This application claims benefit of priority to Korean Patent Application No. 10-2024-0064344, filed on May 17, 2024, in the Korean Intellectual Property Office, the content of which is incorporated herein by reference in its entirety.

### BACKGROUND

### 1. Field

Embodiments of the present disclosure relate to a semiconductor device.

### 2. Brief Description of Background Art

In a process of manufacturing a power device such as a display driver integrated circuit (DDI) in a semiconductor integrated circuit device, in addition to a low-voltage transistor for logic operating at a low voltage, a high-voltage transistor for driving a liquid crystal display (LCD) operating at a high voltage should be implemented simultaneously on a semiconductor substrate. In general, a high-voltage transistor includes a thick gate oxide film, and may have a structure such as a modified lightly doped drain (MLDD) or a field lightly doped drain (FLDD). A device isolation region for implementing these devices may adopt a shallow trench isolation (STI) structure using a trench technology to improve a degree of integration.

### SUMMARY

According to embodiments of the present disclosure, a semiconductor device may be provided that can prevent leakage current in a semiconductor device having a lightly doped drain (LDD) structure, such as a double doped drain (DDD) structure.

According to embodiments of the present disclosure, a semiconductor device may be provided and include: a semiconductor substrate; an active region on the semiconductor substrate; a device isolation region on a side surface of the active region; a first source/drain region and a second source/drain region spaced apart from each other within the active region; a channel region between the first source/drain region and the second source/drain region, within the active region; a gate electrode extending across the active region in a first direction and onto the device isolation region, and vertically overlapping the channel region, the gate electrode including a first side surface and a second side surface opposite to each other in a second direction, perpendicular to the first direction; a first gate spacer on the first side surface of the gate electrode; a second gate spacer on the second side surface of the gate electrode; a gate insulating layer between the active region and the gate electrode; and a first blocking layer on the first gate spacer and a portion of the first source/drain region, wherein the first source/drain region includes: a first high-concentration impurity region that does not vertically overlap with the gate electrode; and a first low-concentration impurity region between the channel region and the first high-concentration impurity region, vertically overlapping with the first gate spacer, and having a lower impurity concentration than an impurity concentration of the first high-concentration impurity region, wherein the active region includes a first side surface and a second side surface opposite to each other in the first direction, wherein the device isolation region includes a first device isolation portion on the first side surface of the active region and a second device isolation portion on the second side surface of the active region, and wherein the first blocking layer includes: a first blocking portion extending in the first direction; a second blocking portion extending from the first blocking portion in the second direction, and on a portion of the first device isolation portion; and a third blocking portion extending from the first blocking portion in the second direction, and on a portion of the second device isolation portion.

According to embodiments of the present disclosure, a semiconductor device may be provided and include: a semiconductor substrate; an active region on the semiconductor substrate; a device isolation region on a side surface of the active region; a first source/drain region and a second source/drain region spaced apart from each other within the active region; a channel region between the first source/drain region and the second source/drain region, within the active region; a gate electrode extending across the active region in a first direction and onto the device isolation region, and vertically overlapping the channel region, the gate electrode including a first side surface and a second side surface opposite to each other in a second direction, perpendicular to the first direction; a first gate spacer on the first side surface of the gate electrode; a second gate spacer on the second side surface of the gate electrode; a gate insulating layer between the active region and the gate electrode; a first blocking layer on a portion of the first source/drain region; and a first metal-semiconductor compound layer on the first source/drain region and exposed by the first blocking layer, wherein the first source/drain region includes: a first high-concentration impurity region not vertically overlapping with the gate electrode; and a first low-concentration impurity region vertically overlapping with the first gate spacer, and between the channel region and the first high-concentration impurity region, wherein the first low-concentration impurity region has a lower impurity concentration than an impurity concentration of the first high-concentration impurity region, wherein the active region includes a first side surface and a second side surface opposite to each other in the first direction, wherein the device isolation region includes a first device isolation portion on the first side surface of the active region and a second device isolation portion on the second side surface of the active region, and wherein the first blocking layer includes: a first blocking portion extending in the first direction on the first source/drain region; a second blocking portion extending in the second direction from a first end of the first blocking portion in the first direction, and on a boundary region between the first device isolation portion and the active region; and a third blocking portion extending in the second direction from a second end of the first blocking portion, opposite of the first end of the first blocking portion, and on a boundary region between the second device isolation portion and the active region.

According to embodiments of the present disclosure, a semiconductor device may be provided and include: a semiconductor substrate including a first conductivity-type transistor region and a second conductivity-type transistor region; a device isolation region defining active regions within the first conductivity-type transistor region and the second conductivity-type transistor region; first source/drain regions and second source/drain regions spaced apart from each other in each of the active regions; channel regions between the first source/drain regions and the second source/drain regions, in each of the active regions; gate electrodes extending across each of the active regions in a first direction and onto the device isolation region, and vertically overlapping with each of the channel regions, the gate electrodes having a first side surface and a second side surface opposite to each other in a second direction, perpendicular to the first direction; first gate spacers on the first side surface of each of the gate electrodes; second gate spacers on the second side surface of each of the gate electrodes; gate insulating layers between the active regions and each of the gate electrodes; a first blocking layer on a portion of each of the first source/drain regions; and first metal-semiconductor compound layers on the first source/drain regions and exposed by the first blocking layer, wherein each of the first source/drain regions includes: a first high-concentration impurity region not vertically overlapping with at least one of the gate electrodes; and a first low-concentration impurity region vertically overlapping with at least one of the first gate spacers, the first low-concentration impurity region being between at least one of the channel regions and the first high-concentration impurity region, and having a lower impurity concentration than an impurity concentration of the first high-concentration impurity region, wherein each of the active regions includes a first side surface and a second side surface opposite to each other in the first direction, wherein the device isolation region includes a first device isolation portion on the first side surface of each of the active regions and a second device isolation portion on the second side surface of each of the active regions, and wherein the first blocking layer includes: a first blocking portion extending in the first direction, on each of the first source/drain regions; a second blocking portion extending in the second direction from a first end of the first blocking portion in the first direction, and on a boundary region between the first device isolation portion and one of the active regions; and a third blocking portion extending in the second direction from a second end of the first blocking portion, opposite of the first end of the first blocking portion, and on a boundary region between the second device isolation portion and the one of the active regions.

### BRIEF DESCRIPTION OF DRAWINGS

The above and other aspects, features, and advantages of embodiments of the present disclosure will be more clearly understood from the following detailed description, taken in conjunction with the accompanying drawings:

FIG. 1 is plan view of a semiconductor device according to an example embodiment of the present disclosure;

FIG. 2 is an exploded perspective view of the semiconductor device of FIG. 1;

FIGS. 3A to 3C are cross-sectional views of the semiconductor device of FIG. 1;

FIGS. 4 and 5 are plan views of a semiconductor device according to an example embodiment of the present disclosure;

FIG. 6 is a plan view of a semiconductor device according to an example embodiment of the present disclosure;

FIG. 7 is a cross-sectional view of the semiconductor device of FIG. 6;

FIG. 8 is a cross-sectional view of a semiconductor device according to an example embodiment of the present disclosure;

FIG. 9 is a plan view of a semiconductor device according to an example embodiment of the present disclosure; and

FIGS. 10A to 10C are cross-sectional views illustrating a method of manufacturing a semiconductor device according to an example embodiment of the present disclosure.

### DETAILED DESCRIPTION

Hereinafter, various non-limiting example embodiments of the present disclosure will be described in detail with reference to the attached drawings.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

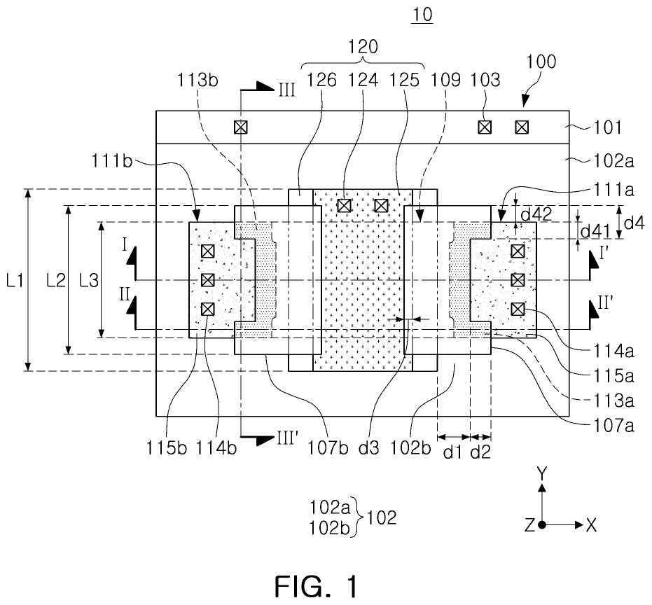

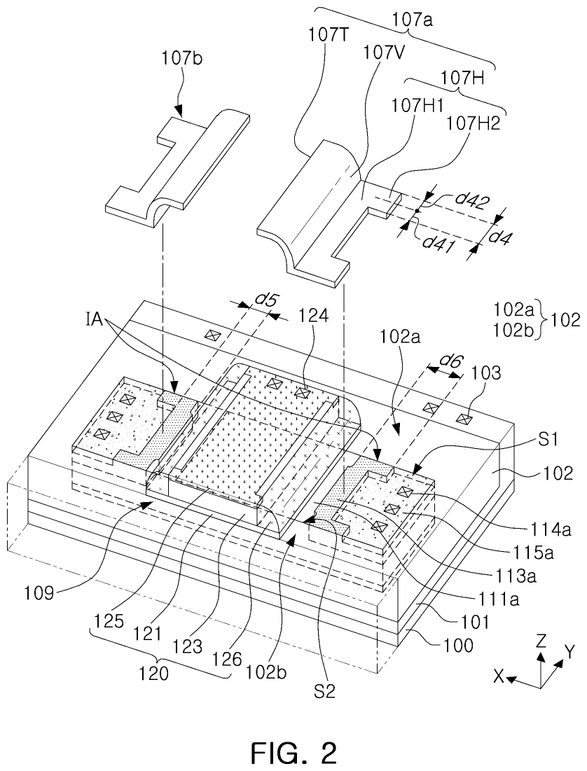

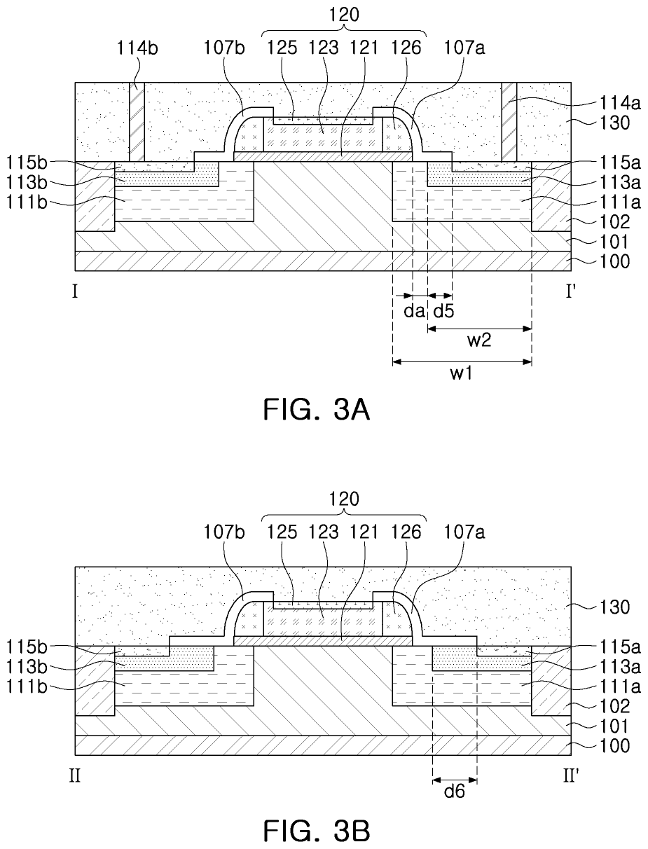

Referring to FIGS. 1 and 3C, a semiconductor device 10 of an example embodiment of the present disclosure will be described. FIG. 1 is a plan view of the semiconductor device 10 according to an example embodiment of the present disclosure, FIG. 2 is an exploded perspective view of the semiconductor device 10 of FIG. 1, and FIGS. 3A to 3C are cross-sectional views of the semiconductor device 10 of FIG. 1. FIG. 3A is a cross-sectional view taken along a line I-I′ of FIG. 1, FIG. 3B is a cross-sectional view taken along a line II-II′ of FIG. 1, and FIG. 3C is a cross-sectional view taken along a line III-III′ of FIG. 1.

FIGS. 1 to 3C illustrate a high voltage (HV) region in which a high-voltage transistor is formed. In some cases, a low voltage (LV) region in which a low-voltage transistor is formed may be formed within the same substrate 100. For example, in a display driver integrated circuit (IC) (DDI) device, a high-voltage transistor for driving a light-emitting element may be formed in the HV region, and a low-voltage transistor for logic may be formed in the LV region. Embodiments of the present disclosure are not limited to LDI devices, and may be applied to various types of semiconductor devices 10 in which a high-voltage transistor is formed in the HV region.

Referring to FIGS. 1 to 3C, the semiconductor device 10 may include a high-voltage transistor within a semiconductor substrate 100.

The semiconductor substrate 100 may include bulk silicon or silicon-on-insulator (SOI). Alternatively, the semiconductor substrate 100 may be a silicon semiconductor substrate, or may include other materials such as, for example, silicon germanium (SiGe), indium antimonide (InSb), lead telluride, indium arsenide (InAs), indium phosphide (InP), gallium arsenide (GaAs), or gallium antimonide (GaSb). In addition, the semiconductor substrate 100 may be a semiconductor substrate in which an epitaxial layer is formed on a base semiconductor substrate.

The semiconductor substrate 100 may be a first conductivity-type semiconductor substrate, and may be, for example, a P-type semiconductor substrate. Depending on the type of high-voltage transistor in the HV region within the semiconductor substrate 100, at least one well 101 that may be a first conductivity-type well and/or a second conductivity-type well may be disposed.

For example, when the semiconductor substrate 100 is a first conductivity-type semiconductor substrate, a well 101 that is a second conductivity-type well may be formed by performing an ion implantation process using a second conductivity-type impurity from the upper surface to a predetermined depth, and when the first conductivity-type semiconductor substrate is a P-type semiconductor substrate, a second conductivity-type semiconductor substrate may be an N-type semiconductor substrate.

A device isolation region (STI) 102, that may be trench-shaped, may be disposed in a predetermined region of the semiconductor substrate 100. The device isolation region 102 may define an active region 109 in which the transistor operates. A gate structure 120 may be disposed above the active region 109. The gate structure 120 may be formed to extend across the active region 109 and to a portion of the device isolation region 102. Meanwhile, within the active region 109, source/drain regions may be formed to be spaced apart from each other in the X-direction at a constant interval, and a channel region may be disposed therebetween, and the gate structure 120 may extend over the channel region in the Z-direction.

The device isolation region 102 may define an active region 109 in which each transistor device is formed in a subsequent process within the first/second conductivity-type well (e.g., the at least one well 101), and the semiconductor substrate 100 may be divided into a field region in which the device isolation region 102 is formed and an active region 109 in which the device isolation region 102 is not formed. The device isolation region 102 may be formed as a trench device isolation region through a shallow trench isolation (STI) process, or the like, and may be formed by, for example, depositing an oxide film such as silicon oxide.

The gate structure 120 may be formed by stacking a gate insulating layer 121 and a gate electrode layer 123 on the active region 109, and then patterning the gate insulating layer 121 and the gate electrode layer 123. The gate insulating layer 121 may include silicon oxide, and the gate electrode layer 123 may include polysilicon.

The gate insulating layer 121 may be formed relatively thickly in the case of a high-voltage transistor, and may satisfy a thickness of, for example, 150 Å to 1000 Å.

The source/drain regions disposed to be spaced apart in an X-direction perpendicular to a longitudinal direction (Y-direction) of the gate structure 120 may include low-concentration impurity regions 111a and 111b, and high-concentration impurity regions 113a and 113b into which impurity ions are implanted at a higher concentration than that of the low-concentration impurity regions 111a and 111b.

The low-concentration impurity regions 111a and 111b disposed in a main portion of the source/drain region may be disposed to be spaced apart from each other on both sides of the gate structure 120 in the X-direction perpendicular to the longitudinal direction (Y-direction) of the gate structure 120, and may be formed at a predetermined depth from the upper surface of the semiconductor substrate 100.

Within the first/second conductivity-type well (e.g., the well 101), low-concentration impurity regions 111a and 111b may be disposed on both sides of the gate structure 120, and high-concentration impurity regions 113a and 113b may be disposed at a predetermined depth from the upper surface of the semiconductor substrate 100 above the low-concentration impurity regions 111a and 111b. When the low-concentration impurity regions 111a and 111b have a width w1 in the X-direction, the high-concentration impurity regions 113a and 113b may be formed to have a width w2, smaller than the width w1 of the low-concentration impurity regions 111a and 111b by being spaced apart from the gate structure 120 in the X-direction.

The low-concentration impurity regions 111a and 111b and high-concentration impurity regions 113a and 113b can be formed by ion implanting impurity ions of the same conductive type at different concentrations. As shown in FIGS. 2 to 3B, the high-concentration impurity regions 113a and 113b may be disposed at a distance da in the X-direction from a side surface of the gate structure 120. Low-concentration impurity regions 111a and 111b may be disposed on the upper surface of the semiconductor substrate 100 within the distance da described above. As a degree of integration of semiconductor device 10 is improved and the channel size is reduced, a lightly doped drain (LDD) structure may be formed by forming an extended region with a low doping concentration to prevent leakage current from occurring due to a strong electric field (E-field) and hot carrier effect.

The low-concentration impurity regions 111a and 111b may be formed by ion implanting second/first conductivity-type impurities at a low concentration into the active region 109 exposed to both sides of the gate structure 120 using the gate electrode layer 123 of the gate structure 120 as a mask.

When the first conductivity-type/second conductivity-type well (e.g., the well 101) is a P-type well (e.g., the well 101), the source/drain region may be ion-implanted into N-type impurities such as, for example, phosphorous, arsenic, and the like. When the first conductivity-type/second conductivity-type well (e.g., the well 101) is an N-type well, the source/drain region may be ion-implanted with P-type impurities such as, for example, boron, aluminum, and the like.

The low-concentration impurity regions 111a and 111b may be disposed symmetrically with each other in the active region 109, that is exposed, on both sides of the gate structure 120 at a first depth, to have the width w1 in the X-direction.

The gate structure 120 may include gate spacers 126 on both side surfaces of the low-concentration impurity regions 111a and 111b in the X-direction, respectively. The gate spacers 126 may be formed by depositing an insulating material on both side surfaces of the gate electrode layer 123, and a gate induced drain leakage (GIDL) phenomenon caused by hot carriers generated by an electric field intensified by the low-concentration impurity regions 111a and 111b overlapping with the gate electrode layer 123 in the Z-direction may be suppressed.

Each of the source/drain regions may include high-concentration impurity regions 113a and 113b on the low-concentration impurity regions 111a and 111b, and each of the high-concentration impurity regions 113 and 113b may be disposed adjacent to the device isolation region 102, and spaced apart from the gate structure 120 by the distance da (e.g., a separation distance) in the X-direction. The high-concentration impurity regions 113a and 113b may have a second depth that is a depth shallower than a depth of the low-concentration impurity regions 111a and 111b. Also, on a plane, low-concentration impurity regions 111a and 111b may exist between the high-concentration impurity regions 113a and 113b and a lower portion of the gate structure 120 (i.e., a channel region).

Accordingly, the high-concentration impurity regions 113a and 113b may be disposed within the low-concentration impurity regions 111a and 111b with a shallower depth and smaller width (e.g., the width w2) than the low-concentration impurity regions 111a and 111b, and the high-concentration impurity regions 113a and 113b may function as an actual source/drain region.

Metal-semiconductor compound layers 115a and 115b may be respectively disposed above the high-concentration impurity regions 113a and 113b.

The metal-semiconductor compound layers 115a and 115b may be a region for ohmic contact, may be disposed on the high-concentration impurity regions 113a and 113b, and may have a smaller area than an area of the high-concentration impurity regions 113a and 113b, and a shallower thickness than a thickness of the high-concentration impurity region 113a and 113b. For example, the metal-semiconductor compound layers 115a and 115b may have the same length (Y-direction) as the high-concentration impurity regions 113a and 113b, but may include a smaller width (X-direction), and may be disposed adjacent to the device isolation region 102. The metal-semiconductor compound layer 115a and 115b may be surrounded by the high-concentration impurity regions 113a and 113b and the device isolation region 102, when viewed on a plane, and may be physically/electrically separated from the low-concentration impurity regions 111a and 111b. The metal-semiconductor compound layers 115a and 115b may be formed by forming a thin metal layer for silicidation such as, for example, a metal layer such as titanium or cobalt, and then annealing the same in order to silicidate the same, and then ohmic contact with contact plugs 114a and 114b formed thereafter may be performed.

The metal-semiconductor compound layers 115a and 115b may also be disposed on at least a portion of the upper surface of the gate electrode layer 123 of the gate structure 120, and the gate metal-semiconductor compound layer 125 formed on a portion of the gate electrode layer 123 may perform ohmic contact with the gate contact plugs (e.g., the contact plugs 124) formed thereafter.

The semiconductor device 10 may further include blocking layers (e.g., a first blocking layer 107a and a second blocking layer 107b) to partially form the metal-semiconductor compound layer 115a, the metal-semiconductor compound layer 115b, and the gate metal-semiconductor compound layer 125. The blocking layers (e.g., the first blocking layer 107a and the second blocking layer 107b) may be silicide blocking layers, which can prevent the formation of metal-semiconductor compound layers 115a and 115b in the low-concentration impurity regions 111a and 111b exposed on an upper surface of the semiconductor substrate 100. The blocking layers (e.g., the first blocking layer 107a and the second blocking layer 107b) may extend from the gate structure 120, and may be bent toward the active region 109 and disposed on the upper surface of the semiconductor substrate 100 to expose the metal-semiconductor compound layers 115a and 115b.

In the blocking layers (e.g., the first blocking layer 107a and the second blocking layer 107b), the first blocking layer 107a disposed in the source region and the second blocking layer 107b disposed in the drain region may be disposed such as to be a mirrored pair with respect to the gate structure 120, in the X-direction. Because the blocking layers (e.g., the first blocking layer 107a and the second blocking layer 107b) may have the same structure as each other, one of the blocking layers (e.g., the first blocking layer 107a or the second blocking layer 107b) will be described below, and such description may be equally applied to the other one of the blocking layers.

Referring to FIG. 2, the blocking layers (e.g., the first blocking layer 107a and the second blocking layer 107b) may include a vertical portion 107V covering a side surface of the gate structure 120 and a horizontal portion 107H covering the active region 109.

Specifically, the blocking layers (e.g., the first blocking layer 107a and the second blocking layer 107b) may include a vertical portion 107V covering the side surface of the gate structure 120 (i.e., the gate spacers 126), and may include a horizontal portion 107H bent from the vertical portion 107V, and disposed parallel to the upper surface of the semiconductor substrate 100, and covering all of the low-concentration impurity regions 111a and 111b on the semiconductor substrate 100 and exposing the metal-semiconductor compound layers 115a and 115b.

The horizontal portion 107H may be disposed in a right-angled sidewise “U” shape as illustrated in FIG. 2. The horizontal portion 107H may include a first region 107H1 crossing the active region 109 in the Y-direction and a plurality of second regions 107H2 protruding from the first region 107H1 to cover a boundary region IA between the device isolation region 102 and the active region 109.

In respective blocking layers (e.g., the first blocking layer 107a and the second blocking layer 107b), the second regions 107H2 may protrude from both ends of the first region 107H1 in the X-direction to form a right-angled sidewise “U” shape, but embodiments of the present disclosure are not limited thereto.

When the active region 109 includes two first side surfaces S1 and second side surfaces S2, opposing each other in the Y-direction, the device isolation region 102 facing the first side surface S1 may define a first device isolation portion 102a, and the device isolation region 102 facing the second side surface S2 may define a second device isolation portion 102b.

The first region 107H1 of the horizontal portion 107H may have a first width d1 in the X-direction, and the first width d1 may be greater than the distance da between the high-concentration impurity regions 113a and 113b and the gate structure 120.

When the gate structure 120 is disposed to have a first length L1 in the Y-direction, the horizontal portion 107H may extend to have a second length L2 in the Y-direction, and the second length L2 may be smaller than the first length L1 of the gate structure 120, but embodiments of the present disclosure are not limited thereto.

The second length L2 of the horizontal portion 107H may be greater than a third length L3 of the active region 109 in the Y-direction. Therefore, the horizontal portion 107H may be disposed to cover the boundary region IA between the active region 109 and the device isolation region 102 on the upper surface of the semiconductor substrate 100. Accordingly, the first region 107H1 may cover a portion of the first source/drain region not vertically overlapping with the gate spacer 126, the first device isolation portion 102a, and the second device isolation portion 102b.

The horizontal portion 107H may include a plurality of the second regions 107H2 respectively protruding from the first region 107H1 in the X-direction. The plurality of second regions 107H2 may respectively protrude from both ends of the first region 107H1 in the X-direction in a direction away from the gate structure 120, and may be disposed to respectively cover the boundary region IA between the active region 109 and the device isolation region 102. Accordingly, first ones of the second regions 107H2 may extend from the portion of the first region 107H1 covering the source/drain region and the first device isolation portion 102a, in contact with each other, in a direction away from the gate structure 120 to cover the first source/drain region and the first device isolation portion 102a, in contact with each other.

Meanwhile, second ones of the second region 107H2 may extend from the portion of the first region 107H1 covering the source/drain region and the second device isolation portion 102b, in contact with each other, in a direction away from the gate structure 120 to cover the first source/drain region and the second device isolation portion 102b, in contact with each other.

The first and second ones of the second regions 107H2 may have a fourth length d4 in the Y-direction and a second width d2 in the X-direction. The fourth length d4 may be smaller than the second width d2, and the second width d2 may be smaller than a maximum length of an entirety of the metal-semiconductor compound layers 115a and 115b in the X-direction. Accordingly, metal-semiconductor compound layers 115a and 115b may be formed within the active region 109 exposed by the horizontal portion 107H, and the metal-semiconductor compound layers 115a and 115b may have a “T” shape, but embodiments of the present disclosure are not limited thereto.

A first portion of the first ones of the second regions 107H2, covering the source/drain region may have a 4-1 length d41 in the Y-direction, and a second portion thereof, covering the first device isolation portion 102a and the second device isolation portion 102b may have a 4-2 length d42. The 4-1 length d41 of the first portion may be equal to the length of the high-concentration impurity regions 113a and 113b at the boundary region IA. Accordingly, the first portion of the second ones of the second regions 107H2 may be disposed above portions of the high-concentration impurity regions 113a and 113b adjacent to the first device isolation portion 102a to cover the high-concentration impurity regions 113a and 113b, and first portions of other second regions 107H2 may be disposed above portions of the high-concentration impurity regions 113a and 113b adjacent to the second device isolation portion 102b to cover the high-concentration impurity regions 113a and 113b.

Since the first portion of the second regions 107H2 of the blocking layers (e.g., the first blocking layer 107a and the second blocking layer 107b) may be disposed above the high-concentration impurity regions 113a and 113b, so that a separation distance d6 between the low-concentration impurity regions 111a and 111b and the metal-semiconductor compound layers 115a and 115b below the second region 107H2 may be larger than the separation distance d5 below the first region 107H1.

The blocking layers (e.g., the first blocking layer 107a and the second blocking layer 107b) may function not only as a mask for forming metal-semiconductor compound layers 115a and 115b, but also as a doping mask for ion implantation for forming high-concentration impurity regions 113a and 113b. When impurities are ion-implanted and driven in during the formation of the high-concentration impurity regions 113a and 113b, the high-concentration impurity regions 113a and 113b may be partially formed below the blocking layers (e.g., the first blocking layer 107a and the second blocking layer 107b) by diffusion of the impurities, specifically, in an edge region of the blocking layers (e.g., the first blocking layer 107a and the second blocking layer 107b). Referring to FIGS. 2, 3A, and 3B, it can be confirmed that the edge region of the blocking layers (e.g., the first blocking layer 107a and the second blocking layer 107b) and a portion of the high-concentration impurity regions 113a and 113b overlap in the Z-direction, and such diffusion of impurities may be a region spontaneously formed by the ion implantation and drive-in process. Thereafter, when silicidation is performed using the blocking layers (e.g., the first blocking layer 107a and the second blocking layer 107b) as a mask, a thin metal layer for silicidation is disposed only on an area exposed by the blocking layers (e.g., the first blocking layer 107a and the second blocking layer 107b), and silicidation is performed by the corresponding area. There may be a difference in an area between the metal-semiconductor compound layers 215a and 115b and the high-concentration impurity regions 113a and 113b, and a portion of the high-concentration impurity regions 113a and 113b forming the difference in area may be disposed below the edge region of the blocking layers (e.g., the first blocking layer 107a and the second blocking layer 107b).

As described above, high-concentration impurity regions 113a and 113b may be disposed between the metal-semiconductor compound layers 115a and 115b and the low-concentration impurity regions 111a and 111b due to the difference in area, and by physically separating the metal-semiconductor compound layers 115a and 115b and the low-concentration impurity regions 111a and 111b by the high-concentration impurity regions 113a and 113b, leakage current can be blocked. By forming the blocking layers (e.g., the first blocking layer 107a and the second blocking layer 107b) in a right-angled sidewise “U” shape so that the blocking layers (e.g., the first blocking layer 107a and the second blocking layer 107b) protrude on a boundary region IA between the first device isolation portion 102a and the second device isolation portion 102b among the edge region of the blocking layers (e.g., the first blocking layer 107a and the second blocking layer 107b), an area of the high-concentration impurity regions 113a and 113b that diffuses downwardly can be increased. In the boundary region IA between the device isolation region 102 and the active region 109, the high-concentration impurity regions 113a and 113b may be formed to be exposed with a width d6 that is large, so that the separation distance (corresponding to the width d6) between the low-concentration impurity regions 111a and 111b and the metal-semiconductor compound layers 115a and 115b may be increased, thereby reliably separating the low-concentration impurity regions 111a and 111b from the metal-semiconductor compound layers 115a and 115b. Accordingly, it is possible to block leakage current that may occur in the boundary region IA between the active region 109 and the device isolation region 102.

The vertical portion 107V of the blocking layers (e.g., the first blocking layer 107a and the second blocking layer 107b) may extend along a side surface of the gate structure 120 in the Z-direction, and may be formed to have a curved surface as illustrated in FIGS. 3A and 3B, depending on the shape of the gate spacers 126.

In addition, the blocking layers (e.g., the first blocking layer 107a and the second blocking layer 107b) may further include an upper surface portion extending from the vertical portion 107V to an upper surface of the gate electrode layer 123 of the gate structure 120. The upper surface portion 107T may be bent from the vertical portion 107V to cover a portion of the upper surface of the gate electrode layer 123 of the gate structure 120. Accordingly, the gate structure 120 may include the gate metal-semiconductor compound layer 125 on at least a portion of the upper surface of the gate electrode layer 123. A width d3 of the upper surface portion 107T in the X-direction may be smaller than the second width d2 of the second region 107H2 of the horizontal portion 107H.

Each of the blocking layers (e.g., the first blocking layer 107a and the second blocking layer 107b) may be defined as a first blocking portion including a first region 107H1 among the upper surface portion 107T, the vertical portion 107V, and the horizontal portion 107H, and second blocking portions including the second regions 107H2 among the horizontal portions 107H.

Accordingly, the first blocking portion may cover a gate spacer 126, a portion of the source/drain region, not vertically overlapping the gate spacer 126, a first device isolation portion 102a, and the second device isolation portion 102b, and one second blocking portion (furthest in the Y-direction) may cover the source/drain region and the first device isolation portion 102a, in contact with each other, among the first blocking portions, and extend in a direction away from the gate structure 120 to cover the source/drain region and the first device isolation portion 102a, in contact with each other. The second blocking portion (furthest in the negative Y-direction) may cover the source/drain region and the second device isolation portion 102b, in contact with each other, among the first blocking portions, and extend in a direction away from the gate structure 120 to cover the source/drain region and the second device isolation portion 102b, in contact with each other.

The blocking layers (e.g., the first blocking layer 107a and the second blocking layer 107b) may include at least one from among a silicon oxide film and a silicon nitride film, and may have a thickness smaller than the thickness of the gate insulating layer 121 such as, for example, a thickness of 200 Å to 400 Å, or 300 Å or less, but embodiments of the present disclosure are not limited thereto.

An interlayer insulating layer 130 covering both the gate structure 120 and the active region 109 may be formed. The interlayer insulating layer 130 may include an insulating material such as an oxide film, a nitride film, an oxynitride film, an oxygen carbon film, or the like.

Contact plugs 114a, 114b, and 124 penetrating through the interlayer insulating layer 130, and contacting the metal-semiconductor compound layers 115a and 115b of the active region 109 and the gate metal-semiconductor compound layer 125 of the gate structure 120 may be disposed.

The contact plugs 114a, 114b, and 124 may include tungsten, or the like, and may expose and directly contact a portion of the metal-semiconductor compound layers (e.g., the metal-semiconductor compound layers 115a and 115b and the gate metal-semiconductor compound layer 125) to form an ohmic contact.

The semiconductor device 10 may include a body contact region doped with high-concentration impurities for applying a body voltage of the first conductivity-type/second conductivity-type well (e.g., the well 101), and may further include body contact plugs 103 connected to the body contact region.

The semiconductor device 10 may have a plurality of high-voltage transistors disposed within a first conductivity-type well (e.g., the well 101) of the semiconductor substrate 100, and a plurality of high-voltage transistors may also be disposed within a second conductivity-type well (e.g., the well 101), different from the first conductivity-type. In the case of a complementary metal-oxide semiconductor (CMOS) device in which N-channel metal-oxide semiconductor (NMOS) and p-channel metal-oxide semiconductor (PMOS) transistors are disposed within a single semiconductor substrate (e.g., the semiconductor substrate 100), it can function as a transmission gate in a DDI device.

When the semiconductor device 10 operates as a transmission gate, two transistors of different conductivity-types should be turned on/off simultaneously, so blocking of leakage current is very important. According to embodiments of the present disclosure, high-concentration impurity regions 113a and 113b may be disposed between the metal-semiconductor compound layers 115a and 115b and the low-concentration impurity regions 111a and 111b, and in particular, the blocking layers (e.g., the first blocking layer 107a and the second blocking layer 107b) may be formed in a right-angled sidewise “U” shape to cover the boundary region IA between the device isolation region 102 and the source/drain region, so that leakage current that can flow along the boundary region IA between the device isolation region 102 and the source/drain region of the active region 109 may be minimized.

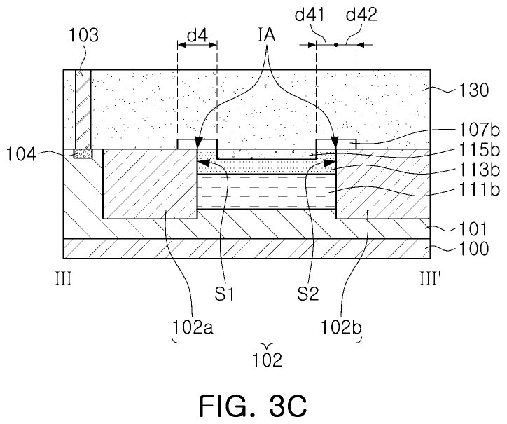

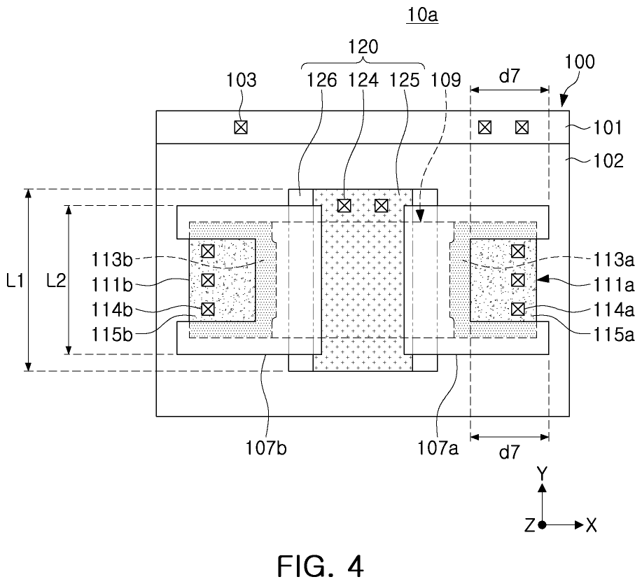

Hereinafter, various embodiments of the present disclosure will be described with reference to FIGS. 4 to 8. FIGS. 4 and 5 are plan views of a semiconductor device according to an example embodiment of the present disclosure.

Referring to FIG. 4, a semiconductor device 10a is the same as the semiconductor device 10 of FIGS. 1 to 3C, except for the shapes of blocking layers (e.g., the first blocking layer 107a and the second blocking layer 107b).

Specifically, the blocking layers (e.g., the first blocking layer 107a and the second blocking layer 107b) of the semiconductor device 10a may include a vertical portion 107V (see FIG. 2) covering a side surface of the gate structure 120, that is, the gate spacer 126, and include a horizontal portion 107H (see FIG. 2) bent from the vertical portion 107V and disposed parallel to the semiconductor substrate 100, and covering all of low-concentration impurity regions 111a and 111b on the semiconductor substrate 100 and exposing metal-semiconductor compound layers 115a and 115b.

The horizontal portion 107H may be disposed in a right-angled sidewise “U” shape. The horizontal portion 107H may include a first region 107H1 (see FIG. 2) crossing the active region 109 in a Y-direction and a plurality of second regions 107H2 (see FIG. 2) protruding from the first region 107H1 to cover a boundary region IA between the device isolation region 102 and the active region 109. For example, the second region 107H2 may protrude in an X-direction from both ends of the first region 107H1 to form a right-angled sidewise “U” shape.

The first region 107H1 of the horizontal portion 107H may have a first width d1 (see FIG. 1) along the X-axis, and the first width d1 may be greater than a separation distance da may be greater than the separation distance da (see FIG. 3A) between the high-concentration impurity regions 113a and 113b and the gate structure 120.

The horizontal portion 107H may extend in the Y-direction to have a second length L2, and the second length L2 may be larger than the third length L3 of the active region 109. Accordingly, the horizontal portion 107H may be disposed to cover the boundary region IA between the active region 109 and the device isolation region 102.

The horizontal portion 107H may include a plurality of second regions 107H2 (see FIG. 2) protruding from the first region 107H1. The plurality of second regions 107H2 may protrude from both ends of the first region 107H1 and may be respectively disposed to cover the boundary region IA between the active region 109 and the device isolation region 102. The second region 107H2 may have a fourth length d4 (see FIG. 2) in the Y-direction and a fourth width d7 in the X-direction. The fourth width d7 may be larger than the first width d1, and the fourth width d7 may be larger than the maximum length of the entirety of the metal-semiconductor compound layers 115a and 115b. Accordingly, the second region 107H2 of the horizontal portion 107H may cross the entirety of the metal-semiconductor compound layers 115a and 115b and ends thereof may extend to the device isolation region 102. Metal-semiconductor compound layers 115a and 115b may be formed on the active region 109 exposed by the horizontal portion 107H, and the metal-semiconductor compound layers 115a and 115b may have a rectangular shape, but embodiments of the present disclosure are not limited thereto.

As described above, the second regions 107H2 of the blocking layers (e.g., the first blocking layer 107a and the second blocking layer 107b) may be formed longer and extend longer than the active region 109, so that the second regions 107H2 may be disposed to cover the entire boundary region IA between the source/drain region of the active region 109 and the device isolation region 102, thereby reliably blocking leakage current. High-concentration impurity regions 113a and 113b may be formed below the edge regions of the blocking layers (e.g., the first blocking layer 107a and the second blocking layer 107b), and it may be implemented so that the high-concentration impurity regions 113a and 113b is disposed between the metal-semiconductor compound layers 115a and 115b, the device isolation region 102, and the low-concentration impurity regions 111a and 111b. Accordingly, leakage current that may occur at the boundary with the device isolation region 102 can be blocked.

The vertical portion 107V of the blocking layers (e.g., the first blocking layer 107a and the second blocking layer 107b) may extend in the Z-direction along the side surface of the gate structure 120, and may be formed to have a curved surface as shown in FIGS. 3A and 3B depending on the shape of the gate spacer 126. The upper surface portion 107T can also be formed in the same manner.

Referring to FIG. 5, a semiconductor device 10b is the same as the semiconductor device 10 of FIGS. 1 to 3C, except for the shapes of the blocking layers (e.g., the first blocking layer 107a and the second blocking layer 107b).

Specifically, the blocking layers (e.g., the first blocking layer 107a and the second blocking layer 107b) of the semiconductor device 10b may include a vertical portion 107V (see FIG. 2) covering the side surface of the gate structure 120, that is, the gate spacer 126, and a horizontal portion 107H (see FIG. 2) bent from the vertical portion 107V and disposed parallel to the semiconductor substrate 100, and covering all of the low-concentration impurity regions 111a and 111b and exposing the metal-semiconductor compound layers 115a and 115b.

The horizontal portion 107H may be disposed in a right-angled sidewise “U” shape. The horizontal portion 107H may include a first region 107H1 (see FIG. 2) crossing the active region in the Y-direction, and a plurality of second regions 107H2 (see FIG. 2) protruding from the first region 107H1 to cover the boundary region IA between the device isolation region 102 and the active region 109. The second region 107H2 may protrude from both ends of the first region 107H1 in the X-direction to form a right-angled sidewise “U” shape, but embodiments of the present disclosure are not limited thereto.

The first region 107H1 of the horizontal portion 107H may have a first width d1 (see FIG. 1) along the X-axis, and the first width d1 may be larger than the separation distance da (see FIG. 3A) between the high-concentration impurity regions 113a and 113b and the gate structure 120.

Meanwhile, the horizontal portion 107H may include a plurality of second regions 107H2 (see FIG. 2) protruding from the first region 107H1. The plurality of second regions 107H2 may be disposed to protrude from both ends of the first region 107H1 to cover the boundary region IA between the active region 109 and the device isolation region 102. The second region 107H2 may have a fourth width d7 in the X-direction. The fourth width d7 may be larger than the first width d1, and the fourth width d7 may be larger than the maximum length of the entirety of the metal-semiconductor compound layers 115a and 115b. Accordingly, the second region 107H2 of the horizontal portion 107H may cross the entirety of the metal-semiconductor compound layer 115a and 115b so that ends thereof may extend to the device isolation region 102. Metal-semiconductor compound layers 115a and 115b may be formed on the active region 109 exposed by the horizontal portion 107H, and the metal-semiconductor compound layers 115a and 115b may have a rectangular shape, but embodiments of the present disclosure are not limited thereto.

The horizontal portion 107H may extend to have a fourth length L4 (see FIG. 2) in the Y-direction, and the fourth length L4 may be larger than the third length L3 of the active region 109. Accordingly, the horizontal portion 107H may be disposed to cover the boundary region IA between the active region 109 and the device isolation region 102.

In this case, the fourth length L4 of the horizontal portion 107H may be larger than the first length L1 of the gate structure 120, and the second region 107H2 of the horizontal portion 107H may have a fifth length d9 in the Y-direction, and the second region 107H2 may be expanded so that a region in which the second region 107H2 covers the device isolation region 102 is larger than a region in which the second region 107H2 covers the active region 109.

Accordingly, the vertical portion 107V of the blocking layers (e.g., the first blocking layer 107a and the second blocking layer 107b) may be bent from the horizontal portion 107H and extend along a side surface of the gate structure 120 in the Z-direction, and may be disposed to surround an edge of the side surface of the gate structure 120 by the fourth length L4 of the horizontal portion 107H, that is greater than the first length L1 of the gate structure 120 by a predetermined length d8, but embodiments of the present disclosure are not limited thereto.

The second region 107H2 may be formed longer and be disposed to completely cover the active region 109, so that the second region 107H2 may be disposed to cover the entire boundary region IA between the active region 109 and the device isolation region 102, thereby further blocking leakage current. High-concentration impurity regions 113a and 113b may be formed therebelow along the edge regions of the blocking layers (e.g., the first blocking layer 107a and the second blocking layer 107b), and it may be implemented so that the high-concentration impurity regions 113a and 113b is disposed between the metal-semiconductor compound layers 115a and 115b, the device isolation region 102, and the low-concentration impurity regions 111a and 111b. Accordingly, leakage current that may occur at the boundary with the device isolation region 102 can be blocked.

The vertical portions 107V of the blocking layers (e.g., the first blocking layer 107a and the second blocking layer 107b) may extend in the Z-direction along the side surface of the gate structure 120, and the upper surface portion 107T may be bent from both side surfaces of the upper surface of the gate structure 120 and may be formed parallel to the gate metal-semiconductor compound layer 125.

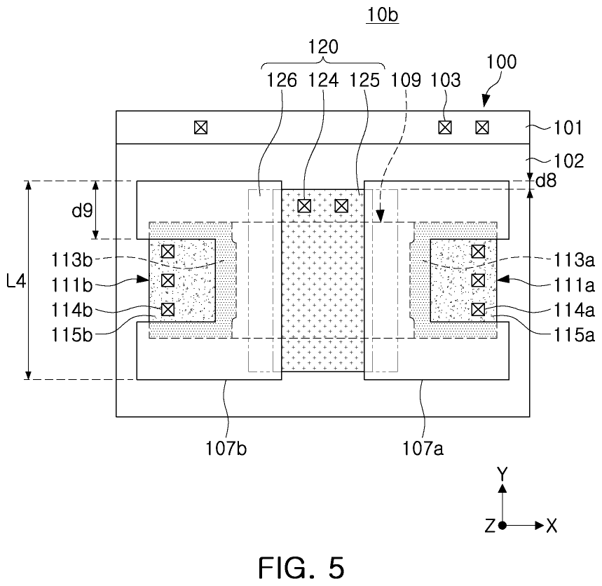

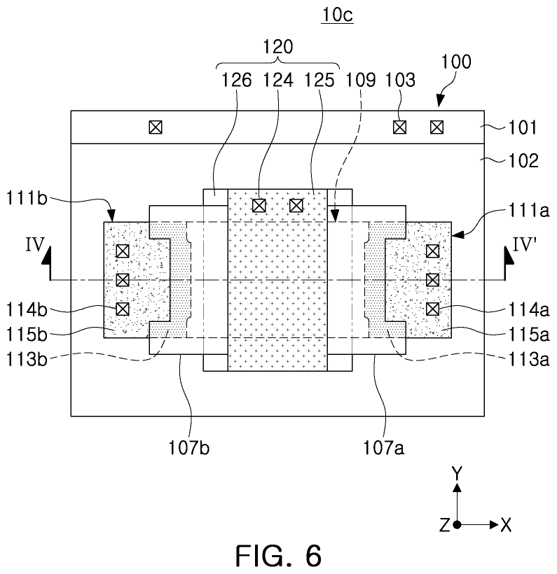

FIG. 6 is a plan view of a semiconductor device 10c according to an example embodiment of the present disclosure, while FIG. 7 is a cross-sectional view of the semiconductor device 10c of FIG. 6 taken along the cutting line IV-IV′.

Referring to FIGS. 6 and 7, the semiconductor device 10c the same as the semiconductor device 10 of FIGS. 1 to 3C, except for the shape of the blocking layers (e.g., the first blocking layer 107a and the second blocking layer 107b).

Specifically, the blocking layers (e.g., the first blocking layer 107a and the second blocking layer 107b) may include a vertical portion 107S covering a side surface of the gate structure 120 (i.e., the gate spacer 126), and a horizontal portion 107H (see FIG. 2) bent from the vertical portion 107V and disposed parallel to the semiconductor substrate 100, and covering all of the low-concentration impurity regions 111a and 111b exposed on the semiconductor substrate 100 and exposing the metal-semiconductor compound layers 115a and 115b.

The horizontal portion 107H may be disposed in a right-angled sidewise “U” shape, and in FIG. 6, it is illustrated to have the same shape as FIG. 1, except that the horizontal portion 107H may also be formed in the same manner as FIG. 4 or FIG. 5.

The vertical portion 107S of the first blocking layer 107a and the second blocking layer 107b may be bent from the horizontal portion 107H along a side surface of the gate structure 120 and extend in a Z-direction. When the gate structure 120 has a first height h1 in the z direction, the vertical portion 107S may have a second height h2, equal to or lower than the first height h1. Accordingly, it may be disposed to cover the side surface of the gate structure 120.

As described above, by disposing the horizontal portion 107H at a second height, equal to or lower than the first height h1, the blocking layers (e.g., the first blocking layer 107a and the second blocking layer 107b) may not include an upper surface portion 107T (see FIG. 2) extending to the upper surface of the gate structure 120.

Accordingly, the entire upper surface of the gate electrode layer 123 of the gate structure 120 may be silicidated to have a gate metal-semiconductor compound layer 125 that is wide, and surface resistance may be reduced thereby.

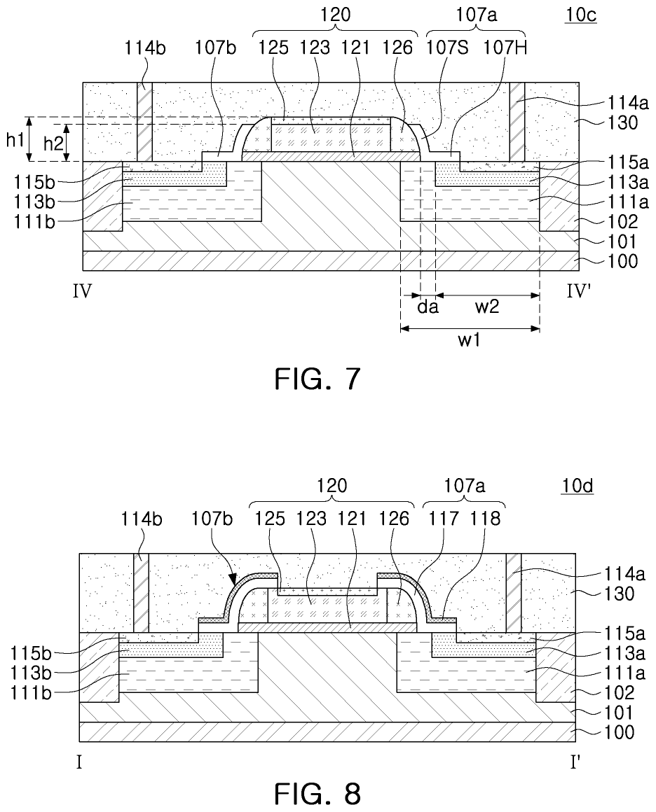

FIG. 8 is a cross-sectional view of a semiconductor device 10d according to an example embodiment of the present disclosure.

Referring to FIG. 8, the semiconductor device 10d is the same as the semiconductor device 10 of FIG. 3A, except for the shape of the blocking layers (e.g., the first blocking layer 107a and the second blocking layer 107b).

Specifically, the blocking layers (e.g., the first blocking layer 107a and the second blocking layer 107b) of the semiconductor device 10d may include a vertical portion 107V (see FIG. 2) covering the side surface of the gate structure 120 (i.e., the gate spacer 126), a horizontal portion 107H (see FIG. 2) bent from the vertical portion 107V and disposed parallel to the semiconductor substrate 100, and an upper surface portion 107T (see. FIG. 2) bent from the horizontal portion 107H and covering at least a portion of the upper surface of the gate structure 120.

The blocking layers (e.g., the first blocking layer 107a and the second blocking layer 107b) may have at least two laminated structures (e.g., at least two sublayers). Specifically, a first blocking sublayer 117 may be disposed to cover at least a portion of the high-concentration impurity regions 113 and 113b, the low-concentration impurity regions 111a and 111b, and the side surface and the upper surface of the gate structure 120. The first blocking layer 117 may include at least one from among silicon oxide, silicon nitride, silicon oxynitride, and silicon oxycarbide.

A second blocking sublayer 118 may be disposed above the first blocking layer 117, and may be formed to conformally cover the first blocking layer 117. Therefore, areas of the second blocking sublayer 118 and the first blocking sublayer 117 may be the same. The second blocking layer 118 may also include at least one from among silicon oxide, silicon nitride, silicon oxynitride, and silicon oxycarbide, but the second blocking sublayer 118 may include a different material from a material of the first blocking sublayer 117. In FIG. 8, it is illustrated that the first blocking layer 107a and the second blocking layer 107b are formed to include two sublayer, but the blocking layers may be formed to include three or five sublayers.

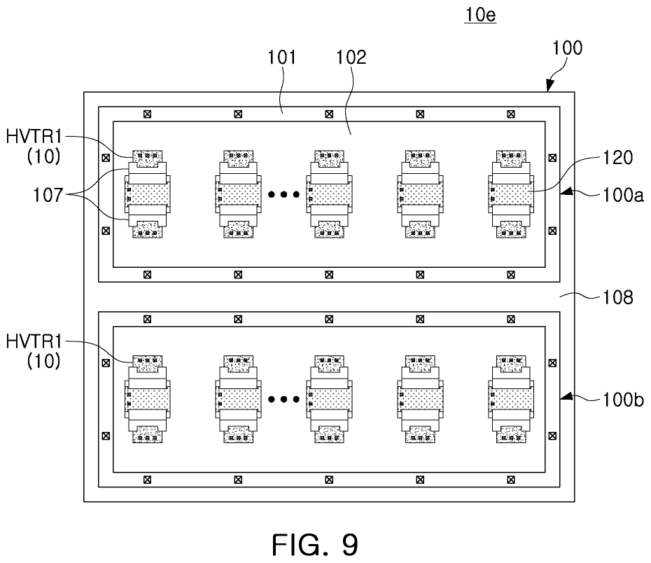

FIG. 9 is a plan view of a semiconductor device 10e according to an example embodiment of the present disclosure.

Referring to FIG. 9, the semiconductor device 10e may include a CMOS transistor including both a first conductivity-type transistor region 100a and a second conductivity-type transistor region 100b within a semiconductor substrate 100.

Specifically, the first conductivity-type transistor region 100a and the second conductivity-type transistor region 100b may be respectively disposed within the semiconductor substrate 100.

The second conductivity-type transistor region 100b may include a first conductivity-type well (e.g., the well 101), as described above, the first conductivity-type transistor region 100a may be partitioned to occupy a portion of the second conductivity-type semiconductor substrate (e.g., the semiconductor substrate 100) without a separate well (e.g., a well 101). However, according to embodiments of the present disclosure, the first conductivity-type transistor region 100a may also form a second conductivity-type well (e.g., the well 101) by ion implanting a predetermined second conductivity-type impurity.

Body contact regions for applying a body voltage may be disposed within the first and/or second conductivity-type well (e.g., the well 101), and the first and/or second conductivity-type well (e.g., the well 101) may be electrically and physically separated by a separation region 108.

A plurality of second conductivity-type transistors HVTR2 may be disposed within the first conductivity-type well (e.g., the well 101), and a plurality of first conductivity-type transistors HVTR1 may be disposed within the second conductivity-type well (e.g., the well 101).

The plurality of second conductivity-type transistors HVTR2 disposed within the first conductivity-type well (e.g., the well 101) may have an active region 109 (see FIG. 1) of respective second conductivity-type transistors HVTR2 defined by a device isolation region 102, and the shapes of respective second conductivity-type transistors HVTR2 may be any one of the semiconductor devices 10 to 10d of FIGS. 1 to 8.

The plurality of first conductivity-type transistors HVTR1 disposed within the second conductivity-type well (e.g., the well 101) may have an active region 109 (see FIG. 1) of respective first conductivity-type transistors HVTR1 defined by a device isolation region 102, and the shapes of respective first conductivity-type transistors HVTR1 may be any one of the semiconductor devices 10 to 10d of FIGS. 1 to 8.

As described above, a semiconductor device 10 (e.g., a CMOS transistor semiconductor device) in which both the first conductivity-type transistors HVTR1 and the second conductivity-type transistors HVTR2 are disposed within one semiconductor substrate 100 may be variously applied depending on the connection of contact plugs 114 and 124.

For example, in the case of a semiconductor device 10e (e.g., a CMOS transistor semiconductor device) applied to an LDI device, the semiconductor device 10e may function as a transmission gate, and when each gate voltage is applied to two gate structures 120 connected in parallel, the two gate structures 120 are turned on/off simultaneously to allow current to flow to a drain. In this case, since a light amount of the allocated pixel can be determined according to the flowing current, an on-off operation without leakage current is required.

As in the semiconductor device 10 to 10d according to an example embodiment of the present disclosure, blocking layers (e.g., the first blocking layer 107a and the second blocking layer 107b) may be disposed to cover a boundary region IA between the device isolation region 102 and the active region 109, so that high-concentration impurity regions 113a and 113b may be disposed between the metal-semiconductor compound layer 115a and 115b and the low-concentration impurity regions 111a, 111b, thereby blocking leakage current.

Hereinafter, a method of manufacturing the semiconductor device 10 of FIGS. 1 to 3C will be described with reference to FIGS. 1, 2, and 10A to 10C.

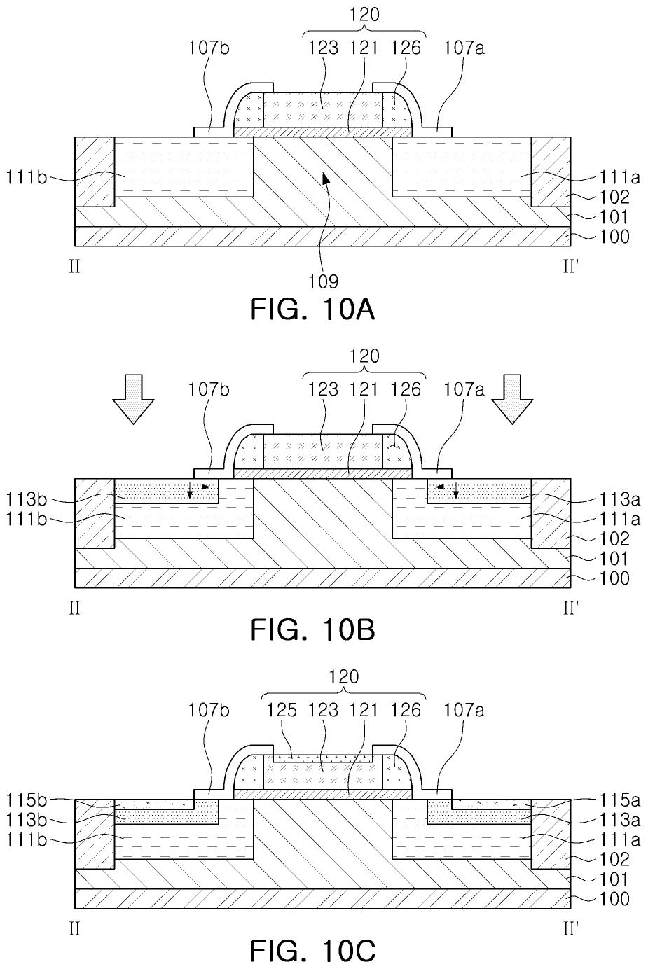

Referring to FIG. 10A, a device isolation region 102 defining an active region 109 may be formed on the semiconductor substrate 100. The device isolation region 102 may be formed through a shallow trench isolation process. The device isolation region 102 may be formed on a side surface of the active region 109.

The semiconductor substrate 100 may include a well region (e.g., a well 101). The well region (e.g., the well 101) may be formed after the device isolation region 102 is formed, or may be formed before the device isolation region 102 is formed.

A gate structure 120 may be formed on the active region 109 and the device isolation region 102.

Forming the gate structure 120 may include sequentially forming a gate insulating layer 121 and a gate conductive layer, patterning the gate conductive layer to form a gate electrode (e.g., the gate electrode layer 123), and forming a gate spacer 126 on a side surface of the gate electrode. The gate insulating layer 121 may be etched after forming the gate spacer 126. The gate insulating layer 121 may be formed below a lower surface of the gate electrode (e.g., the gate electrode layer 123) and a lower surface of the gate spacer 126. The gate spacer 126 may be formed of a single layer or multiple layers.

Low-concentration impurity regions 111a and 111b may be formed.

In an example, forming the low-concentration impurity regions 111a and 111b may include performing a low-concentration ion implantation process for forming a portion of the gate spacer 126, and forming the low-concentration impurity regions 111a and 111b, after forming the gate electrode (e.g., the gate electrode layer 123), and performing a subsequent process for forming the gate spacer 126.

In an example, forming the low-concentration impurity regions 111a and 111b may include performing a low-concentration ion implantation process for forming a gate electrode (e.g., the gate electrode layer 123) and a gate spacer 126, and forming low-concentration impurity regions 111a and 111b.

In the process of forming the low-concentration impurity regions 111a and 111b, the impurities implanted into the active region 109 may diffuse into the active region 109 below the lower surface of the gate spacer 126.

The low-concentration ion implantation process may include implanting impurities with a concentration of 2.0 E¹² to 5.0 E¹³ into the active region 109 with an energy of 150 KeV to 300 KeV.

The ion-implanted impurity may have a conductivity type different from that of the well 101 in which the low-concentration impurity regions 111a and 111b are disposed. For example, in the case of the second conductivity-type well (e.g., the well 101), the first conductivity-type of impurities may be doped.

Blocking layers (e.g., the first blocking layer 107a and the second blocking layer 107b) may be formed. Each of the blocking layers (e.g., the first blocking layer 107a and the second blocking layer 107b) may be formed as a single layer. However, according to embodiments, the blocking layers (e.g., the first blocking layer 107a and the second blocking layer 107b) may be formed to have a multiple layer structure.

The blocking layers (e.g., the first blocking layer 107a and the second blocking layer 107b) may include an insulating material, and may be formed by conformally stacking a silicon oxide film and then patterning the same.

The blocking layers (e.g., the first blocking layer 107a and the second blocking layer 107b) may be formed to have a thickness smaller than a thickness of the gate insulating layer 121, and may be patterned to include a horizontal portion 107H having a right-angled sidewise “U” shape to cover the boundary region IA between the active region 109 and the device isolation region 102, as illustrated in FIGS. 1 and 2.

Referring to FIG. 10B, a high-concentration ion implantation process using the gate structure 120 and the blocking layers (e.g., the first blocking layer 107a and the second blocking layer 107b) as an ion implantation mask may be performed to form high-concentration impurity regions 113a and 113b. The ion implantation of the high-concentration impurity regions 113a and 113b may be formed by implanting impurities of the same conductivity type at a higher concentration as the ion implantation of the low-concentration impurity regions 111a and 111b, and impurities may be ion implanted into the active region 109 in which the blocking layers (e.g., the first blocking layer 107a and the second blocking layer 107b) are not formed. In an example, an impurity having a concentration of 2.0 E¹⁴ to 5.0 E¹⁵ is formed by ion implantation with an energy of 60 KeV to 80 KeV.

When ion implantation is completed, the impurities are diffused by drive-in, and by such a drive-in, the high-concentration impurity regions 113a and 113b may be formed to include an overlapping region overlapping the blocking layers (e.g., the first blocking layer 107a and the second blocking layer 107b) in the Z-direction in an edge region of the blocking layers (e.g., the first blocking layer 107a and the second blocking layer 107b).

In this case, a width d6 (see FIG. 2) of the region of the high-concentration impurity regions 113a and 113b overlapping with the second region 107H2 in the X-direction may be larger than the width d5 of the region of the high-concentration impurity regions 113a and 113b overlapping with the first region 107H1 in the X-direction.

Metal-semiconductor compound layers (e.g., the metal-semiconductor compound layer 115a, the metal-semiconductor compound layer 115b, and the gate metal-semiconductor compound layer 125) may be formed. The metal-semiconductor compound layers) may include metal-semiconductor compound layers 115a and 115b formed on the high-concentration impurity regions 113a and 113b and a metal-semiconductor compound layer 125 formed on the gate electrode layer 123.

When an upper region of the gate electrode layer 123 is formed of metal, the gate metal-semiconductor compound layer 125 formed on the gate electrode layer 123 may be omitted.

Thereafter, an interlayer insulating layer 130 may be stacked, and some regions of the metal-semiconductor compound layers (e.g., the metal-semiconductor compound layer 115a, the metal-semiconductor compound layer 115b, and the gate metal-semiconductor compound layer 125) may be opened to form contact plugs 114a, 114b, and 124, thereby forming the semiconductor device 10 of FIGS. 1 to 3C.

As described above, the metal-semiconductor compound layers 115a and 115b may be formed only in some regions of the high-concentration impurity regions 113a and 113b by the blocking layers (e.g., the first blocking layer 107a and the second blocking layer 107b), and the high-concentration impurity regions 113a and 113b may be formed between the low-concentration impurity regions 111a and 111b and the metal-semiconductor compound layers 115a and 115b, so that a contact between the low-concentration impurity regions 111a and 111b and the metal-semiconductor compound layers 115a and 115b may be blocked.

As set forth above, according to an example embodiment of the present disclosure, by forming a blocking layer to cover the vicinity of a boundary between a trench isolation region and an active region, and selectively siliciding only the active region exposed by the blocking layer, leakage current flowing through the trench isolation region formed between a metal-semiconductor compound layer and a low-concentration impurity region may be blocked.

By covering the vicinity of a boundary between the trench isolation region and the active region, which is the low-concentration impurity region and a high-concentration impurity region, with the blocking layer to form a high-concentration impurity region, and then siliciding the high-concentration impurity region, a high-concentration impurity region exists between the metal-semiconductor compound layer and the low-concentration impurity region, so that leakage current between the metal-semiconductor compound layer and the low-concentration impurity region may be blocked.

The various features, advantages, and effects of embodiments of the present disclosure are not limited to those describe above, and other features, advantages, and effects of embodiments of the present disclosure may be understood by a person of ordinary skill in the art based on the present disclosure. While non-limiting example embodiments have been described above with reference to the accompanying drawings, it will be apparent to those skilled in the art that modifications and variations could be made without departing from the spirit and scope of the present disclosure.

What is claimed is:

1. A semiconductor device, comprising:
a semiconductor substrate;
an active region on the semiconductor substrate;
a device isolation region on a side surface of the active region;
a first source/drain region and a second source/drain region spaced apart from each other within the active region;
a channel region between the first source/drain region and the second source/drain region, within the active region;
a gate electrode extending across the active region in a first direction and onto the device isolation region, and vertically overlapping the channel region, the gate electrode comprising a first side surface and a second side surface opposite to each other in a second direction, perpendicular to the first direction;
a first gate spacer on the first side surface of the gate electrode;
a second gate spacer on the second side surface of the gate electrode;
a gate insulating layer between the active region and the gate electrode; and
a first blocking layer on the first gate spacer and a portion of the first source/drain region,
wherein the first source/drain region comprises:
a first high-concentration impurity region that does not vertically overlap with the gate electrode; and
a first low-concentration impurity region between the channel region and the first high-concentration impurity region, vertically overlapping with the first gate spacer, and having a lower impurity concentration than an impurity concentration of the first high-concentration impurity region,
wherein the active region comprises a first side surface and a second side surface opposite to each other in the first direction,
wherein the device isolation region comprises a first device isolation portion on the first side surface of the active region and a second device isolation portion on the second side surface of the active region, and
wherein the first blocking layer comprises:
a first blocking portion extending in the first direction;
a second blocking portion extending from the first blocking portion in the second direction, and on a portion of the first device isolation portion; and
a third blocking portion extending from the first blocking portion in the second direction, and on a portion of the second device isolation portion.

2. The semiconductor device of claim 1, wherein the first blocking portion is on the first gate spacer, the portion of the first source/drain region, the first device isolation portion, and the second device isolation portion,
wherein the second blocking portion extends from one portion of the first blocking portion, that is on the first source/drain region and the first device isolation portion, such as to be on the first source/drain region and the first device isolation portion,
wherein the third blocking portion extends from another portion of the first blocking portion, that is on the first source/drain region and the second device isolation portion, such as to be on the first source/drain region and the second device isolation portion,
wherein the first source/drain region and the first device isolation portion are in contact with each other below the second blocking portion, and
wherein the first source/drain region and the second device isolation portion are in contact with each other below the third blocking portion.

3. The semiconductor device of claim 2, wherein a first portion of the first high-concentration impurity region is adjacent to the first device isolation portion and is below the second blocking portion, and a second portion of the first high-concentration impurity region is adjacent to the second device isolation portion and is below the third blocking portion.

4. The semiconductor device of claim 3, further comprising:
a metal-semiconductor compound layer on the first high-concentration impurity region.

5. The semiconductor device of claim 4, wherein each of the second blocking portion and the third blocking portion comprises:
a first portion on one from among the first device isolation portion and the second device isolation portion; and
a second portion on the first source/drain region, and
wherein the first high-concentration impurity region is below the second portion of the second blocking portion and the second portion of the third blocking portion.

6. The semiconductor device of claim 5, wherein a length of each of the second blocking portion and the third blocking portion in the second direction is smaller than a maximum length of the metal-semiconductor compound layer in the second direction.

7. The semiconductor device of claim 3, wherein a length of each of the second blocking portion and the third blocking portion in the second direction is smaller than a length, in the second direction, of a region of the first blocking portion that is on the first source/drain region.

8. The semiconductor device of claim 1, wherein the first blocking portion, the second blocking portion, and the third blocking portion comprise a right-angled “U” shape on an upper surface of the semiconductor substrate.

9. The semiconductor device of claim 1, wherein a length of the first blocking layer in the first direction is smaller than a length of the gate electrode in the first direction.

10. The semiconductor device of claim 1, wherein the first blocking layer further comprises an upper surface portion extending from the first blocking portion and on at least a portion of an upper surface of the gate electrode.

11. The semiconductor device of claim 10, wherein a length of the upper surface portion in the second direction is smaller than a length of at least one from among the second blocking portion and the third blocking portion in the second direction.

12. The semiconductor device of claim 10, further comprising:
a gate metal-semiconductor compound layer in a region exposed from the upper surface portion of the upper surface of the gate electrode.

13. The semiconductor device of claim 1, wherein a thickness of the gate insulating layer is greater than a thickness of the first blocking layer.

14. The semiconductor device of claim 1, wherein a thickness of the first blocking layer is 300 Å or less.

15. A semiconductor device, comprising:
a semiconductor substrate;
an active region on the semiconductor substrate;
a device isolation region on a side surface of the active region;
a first source/drain region and a second source/drain region spaced apart from each other within the active region;
a channel region between the first source/drain region and the second source/drain region, within the active region;
a gate electrode extending across the active region in a first direction and onto the device isolation region, and vertically overlapping the channel region, the gate electrode comprising a first side surface and a second side surface opposite to each other in a second direction, perpendicular to the first direction;
a first gate spacer on the first side surface of the gate electrode;
a second gate spacer on the second side surface of the gate electrode;
a gate insulating layer between the active region and the gate electrode;
a first blocking layer on a portion of the first source/drain region; and
a first metal-semiconductor compound layer on the first source/drain region and exposed by the first blocking layer,
wherein the first source/drain region comprises:
a first high-concentration impurity region not vertically overlapping with the gate electrode; and
a first low-concentration impurity region vertically overlapping with the first gate spacer, and between the channel region and the first high-concentration impurity region,
wherein the first low-concentration impurity region has a lower impurity concentration than an impurity concentration of the first high-concentration impurity region,
wherein the active region comprises a first side surface and a second side surface opposite to each other in the first direction, wherein the device isolation region comprises a first device isolation portion on the first side surface of the active region and a second device isolation portion on the second side surface of the active region, and
wherein the first blocking layer comprises:
a first blocking portion extending in the first direction on the first source/drain region;
a second blocking portion extending in the second direction from a first end of the first blocking portion in the first direction, and on a boundary region between the first device isolation portion and the active region; and
a third blocking portion extending in the second direction from a second end of the first blocking portion, opposite of the first end of the first blocking portion, and on a boundary region between the second device isolation portion and the active region.

16. The semiconductor device of claim 15, wherein the second blocking portion and the third blocking portion each comprise one end respectively connected to the first blocking portion and another end, opposite of the one end,
wherein the another end of the second blocking portion is not connected to the another end of the third blocking portion.

17. The semiconductor device of claim 15, wherein the first blocking portion is bent from an upper surface of the semiconductor substrate and extends along the first gate spacer to at least a portion of an upper surface of the gate electrode.

18. The semiconductor device of claim 15, wherein the gate electrode comprises a gate metal-semiconductor compound layer in a region exposed by the first blocking layer on at least a portion of an upper surface of the gate electrode.

19. The semiconductor device of claim 15, wherein the first blocking layer comprises at least two material layers comprising different materials from each other.

20. A semiconductor device, comprising:
a semiconductor substrate comprising a first conductivity-type transistor region and a second conductivity-type transistor region;
a device isolation region defining active regions within the first conductivity-type transistor region and the second conductivity-type transistor region;
first source/drain regions and second source/drain regions spaced apart from each other in each of the active regions;
channel regions between the first source/drain regions and the second source/drain regions, in each of the active regions;
gate electrodes extending across each of the active regions in a first direction and onto the device isolation region, and vertically overlapping with each of the channel regions, the gate electrodes having a first side surface and a second side surface opposite to each other in a second direction, perpendicular to the first direction;
first gate spacers on the first side surface of each of the gate electrodes;
second gate spacers on the second side surface of each of the gate electrodes;
gate insulating layers between the active regions and each of the gate electrodes;
a first blocking layer on a portion of each of the first source/drain regions; and
first metal-semiconductor compound layers on the first source/drain regions and exposed by the first blocking layer,
wherein each of the first source/drain regions comprises:
a first high-concentration impurity region not vertically overlapping with at least one of the gate electrodes; and
a first low-concentration impurity region vertically overlapping with at least one of the first gate spacers, the first low-concentration impurity region being between at least one of the channel regions and the first high-concentration impurity region, and having a lower impurity concentration than an impurity concentration of the first high-concentration impurity region,
wherein each of the active regions comprises a first side surface and a second side surface opposite to each other in the first direction, wherein the device isolation region comprises a first device isolation portion on the first side surface of each of the active regions and a second device isolation portion on the second side surface of each of the active regions, and
wherein the first blocking layer comprises:
a first blocking portion extending in the first direction, on each of the first source/drain regions;
a second blocking portion extending in the second direction from a first end of the first blocking portion in the first direction, and on a boundary region between the first device isolation portion and one of the active regions; and
a third blocking portion extending in the second direction from a second end of the first blocking portion, opposite of the first end of the first blocking portion, and on a boundary region between the second device isolation portion and the one of the active regions.
